(19) United States
(12) Patent Application Publication
(10) Pub. No.: US 2025/0069641 A1
(43) Pub. Date: Feb. 27, 2025

(54) APPARATUS AND METHOD FOR SELECTIVE REFRESH SUPPRESSION

(71) Applicant: Rambus Inc., San Jose, CA (US)

(72) Inventors: Thomas Vogelsang, Jericho, VT (US); Torsten Partsch, Raleigh, NC (US); Wendy Elsasser, Austin, TX (US)

(21) Appl. No.: 18/810,360

(22) Filed: Aug. 20, 2024

Related U.S. Application Data
(60) Provisional application No. 63/534,055, filed on Aug. 22, 2023.

(51) Int. Cl. G11C 11/406; G11C 11/408

(52) U.S. Cl. CPC G11C 11/40618; G11C 11/40615; G11C 11/4085

(57) ABSTRACT

A memory device includes an array of storage cells. Each storage cell is coupled to one of multiple bitlines and one of multiple wordlines. A wordline decoder receives wordline address information and selectively activates an addressed wordline corresponding to the received wordline address information. The wordline decoder includes gating circuitry that is operative during a first mode of operation to selectively suppress activation of the addressed wordline during a refresh operation during a current refresh period based on a timing of an activate command associated with the addressed wordline.

### CROSS-REFERENCE TO RELATED APPLICATIONS

This application is a Non-Provisional that claims priority to U.S. Provisional Application No. 63/534,055, filed Aug. 22, 2023, entitled APPARATUS AND METHOD FOR SELECTIVE REFRESH SUPPRESSION, which is incorporated herein by reference in its entirety.

### TECHNICAL FIELD

The disclosure herein relates to memory systems, memory controllers, memory devices, and associated methods.

### BRIEF DESCRIPTION OF THE DRAWINGS

Embodiments of the disclosure are illustrated by way of example, and not by way of limitation, in the figures of the accompanying drawings and in which like reference numerals refer to similar elements and in which:

FIG. 1 illustrates one embodiment of a memory system that employs a memory controller, and at least one memory device.

FIG. 2 illustrates one embodiment of a wordline decoder utilized in the memory device shown in FIG. 1.

FIG. 3 illustrates one embodiment of a master wordline driver circuit that activates a given master wordline decoded by the wordline decoder of FIG. 2.

FIG. 4 illustrates a sense amplifier enable circuit that operates in coordination with the master wordline driver circuit of FIG. 3.

FIG. 5 illustrates relative timings for one embodiment of a method that suppresses a refresh operation following an activate command.

FIG. 6 illustrates various timings involved in operating various master wordline circuits similar to that shown in FIG. 3.

FIG. 7 illustrates high-level steps employed in operating the master wordline circuit of FIG. 3.

### DETAILED DESCRIPTION

Memory devices, modules, controllers, systems and associated methods are disclosed. In one embodiment, a memory device is disclosed. The memory device includes an array of storage cells. Each storage cell is coupled to one of multiple bitlines and one of multiple wordlines. A wordline decoder receives wordline address information and selectively activates an addressed wordline corresponding to the received wordline address information. The wordline decoder includes gating circuitry that is operative during a first mode of operation to selectively suppress activation of the addressed wordline during a refresh operation during a current refresh period based on a timing of an activate command associated with the addressed wordline. For some embodiments, the gating circuitry is responsive to detection of a stored flag bit associated with a selected one of a set of one-bit latches to selectively suppress activation of a given one of the wordlines by a wordline driver. In other embodiments, register storage is provided to store a count status value of a refresh counter. By employing the gating circuitry to selectively suppress refresh operations when unneeded, such as following an activate command to a given wordline within a refresh interval, power savings may be realized.

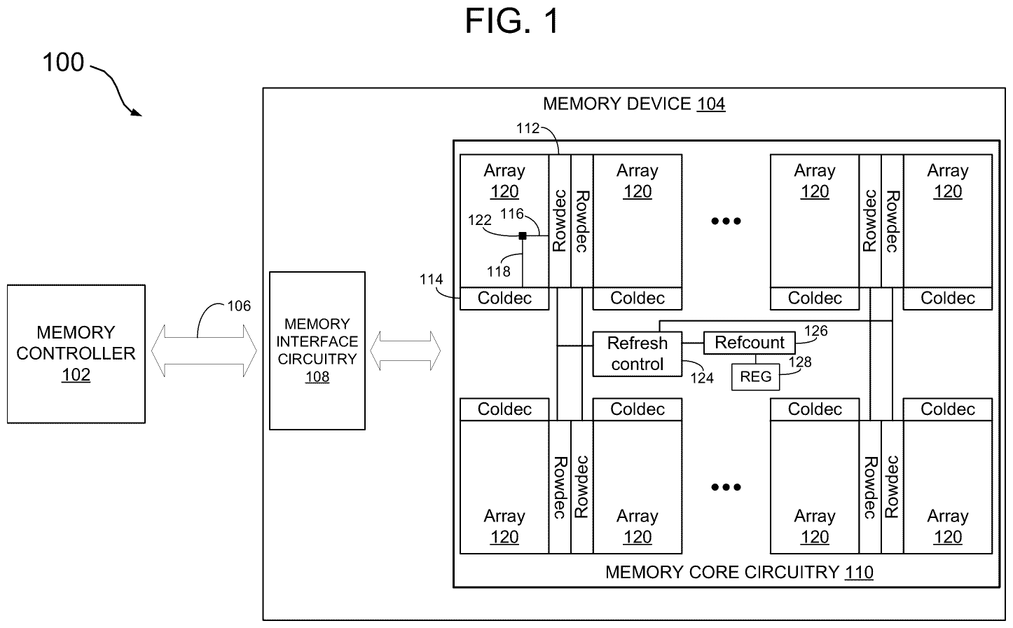

Referring now to FIG. 1, a memory system, generally designated 100, is shown that includes a memory controller 102 coupled to one or more memory devices 104 via signaling media 106. For one embodiment, the memory controller 102 is a dynamic random access memory (DRAM) controller, with the memory device 104 realized as a DRAM memory device. In some embodiments, the memory controller 102 and memory device 104 may be embodied as integrated circuits, or chips. Other embodiments may employ the memory controller 102 as a circuit in a host central processing unit (CPU) (not shown). Specific embodiments for the DRAM memory controller 102 and memory 104 may be compliant with various DRAM standards, including double data rate (DDR) variants, low power (LPDDR) versions, high bandwidth (HBM), and graphics (GDDR) types. Other embodiments may include multi-chip modules that, for example, employ stacked memory die, or stacked packages. Additional embodiments may stack memory die and logic die together in a common package, or in separate packages stacked upon each other. Yet other embodiments may employ multiple memory devices on a substrate (not shown) in a memory module configuration for high-capacity applications.

Further referring to FIG. 1, for one embodiment, each memory device 104 includes memory interface circuitry 108 for handling communications between the memory controller 102 and memory core circuitry 110 of the memory device 104. The memory core circuitry 110 generally includes row decoder circuitry 112 and column decoder circuitry 114 that activate a given wordline and bitline, shown respectively at 116 and 118 for a given one of multiple arrays 120 in response to receiving address information from the memory interface circuitry 108. The activated wordline 116 and bitline 118 cooperate to access a given storage cell 122.

With continued reference to FIG. 1, data stored in the given storage cell 122 is refreshed at a refresh rate determined by refresh control circuitry 124, and sequenced by a refresh counter circuit 126. For one embodiment, register storage 128 is provided to temporarily store a status of the refresh counter circuit 126 that may be accessed by the memory controller 102 to schedule commands for carrying out power-efficient refresh sequences, described more fully below. The register storage 128 may also store configuration settings set by the memory controller 102 to specify certain parameter settings, such as a default retention time, and/or mode settings to, for example, carry out refresh operations in a default legacy mode, or in a power-efficient selective suppression mode described below.

In some embodiments, explained more fully below, the given storage cell 122 may be accessed during a time interval that approaches or occurs more often than a refresh interval associated with the cell. In such circumstances, the retention time of the storage cell 122 may last longer than a timing interval between successive accesses, thus rendering any further refreshes within the retention time interval unnecessary. By providing circuitry in the row decoder circuitry 112 and the refresh control circuitry 124 to cooperate in selectively suppressing refresh operations when unneeded, significant power savings may be realized during operation.

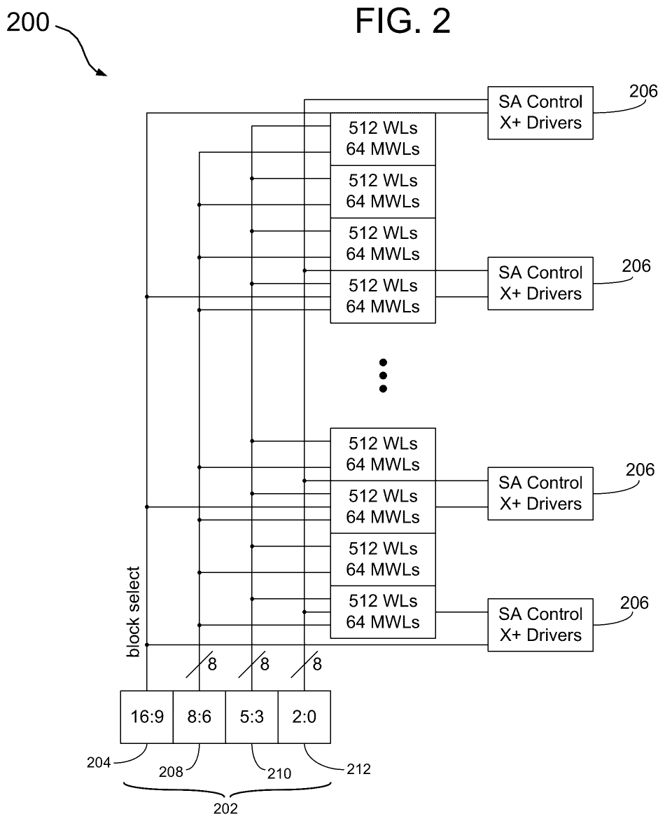

FIG. 2 illustrates one embodiment of a master wordline decoder 200 that may be employed by the row decoder circuitry 112 of FIG. 1. Generally speaking, master wordlines are decoded via a row address hierarchy, where a set of row address bits, such as at 202, provide the selection of a unique local wordline coupled to a master wordline. A most significant bit (MSB) subset of the row address bits 204 [16:9] selects one from multiple blocks 206 of master wordline drivers. Tiers of master wordlines and wordlines are further specified by row address bits [8:6] at 208, and row address bits [5:3], at 210. A specific local wordline selection is made via a least significant bit (LSB) subset of the row address bits [2:0], at 212. For one embodiment, the LSB subset of bits 212 takes the form of a one-hot predecoded address that specifies an X+control signal that activates a positive voltage supply of the specified local wordline.

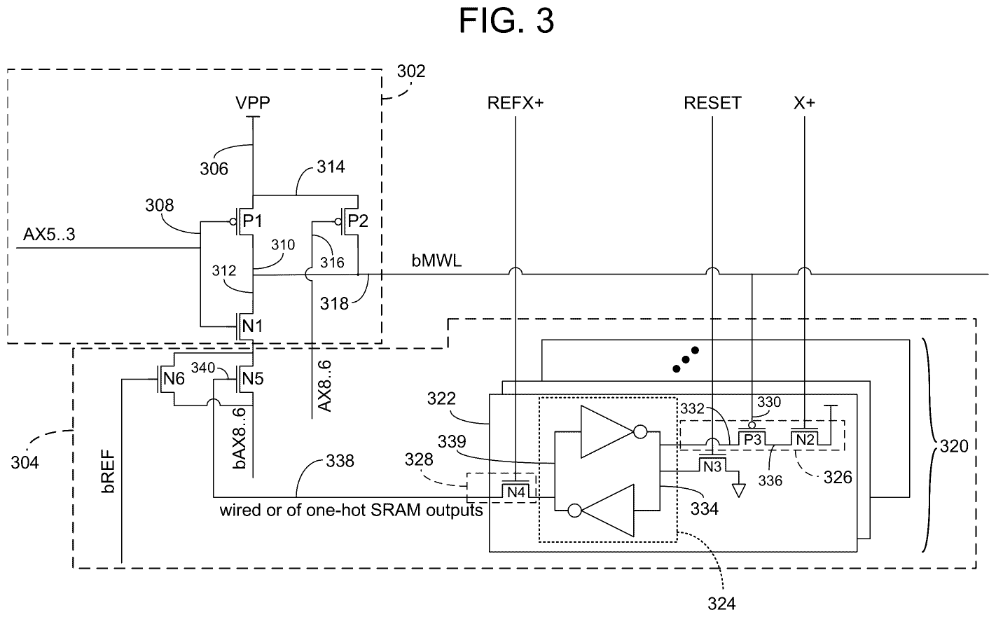

Referring now to FIG. 3, further detail pertaining to a master wordline driver circuit is shown, including activation circuitry 302 to activate an address-specified master wordline, and a gating circuit 304 to selectively suppress activation of the addressed master wordline during certain refresh operations that meet a predefined criteria. For one specific embodiment, the predefined criteria selectively suppresses activation (for a refresh operation in a given refresh period) of an addressed master wordline associated with a given local wordline when both the master wordline and the local wordline have been previously activated within the same given refresh period.

With continued reference to FIG. 3, one embodiment of the activation circuitry 302 includes a first PFET transistor P1 having a drain terminal 306 coupled to source voltage VPP and a source terminal 310 coupled in series to a source terminal 312 of NFET transistor N1. A common gate terminal 308 for both P1 and N1 couples to a one-hot predecoded control signal AX5 . . . 3, provided by the master wordline decoder 200 (FIG. 2). A second PFET transistor P2 includes a drain terminal 314 coupled to the source voltage VPP, a gate terminal 316 to receive one-hot predecoded control signal AX8 . . . 6, and a source terminal 318 that drives a given master wordline bMWL. Transistors P1, P2 and N1 are configured to perform an AND function, such that the master wordline bMWL goes low (to drive the wordline) only when the one-hot predecoded control signals AX5 . . . 3 and AX8 . . . 6 are both in an “on” state.

Further referring to FIG. 3, for one embodiment the gating circuit 304 includes latching logic 320 that employs a separate latch circuit 322 for each local wordline associated with the master wordline bMWL. In some embodiments, eight local wordlines may be associated with a given master wordline, thus eight latch circuits 322 would be provided for the latching logic 320. For one specific embodiment, each latch circuit 322 includes a latch 324 that takes the form of a static random access memory (SRAM) cell to store the flag bit. Each latch circuit 322 includes a write path 326 to write the flag bit to the latch 324, and a read path 328 to read the flag bit. When a flag bit is set, in response to activation of a corresponding local wordline, its value on the read path 328 is the inverse of the value set on the write path 326.

With continuing reference to FIG. 3, the write path 326 includes a PFET write transistor P3 that includes a gate terminal 330 tied to the master wordline bMWL, a source terminal 332 coupled to a write storage line 334 of the SRAM latch 324, and a drain terminal 336 coupled in series to an NFET transistor N2 that is responsive to an X+control signal. A flag bit is written to the latch when both the master wordline bMWL is driven low (activated), and the local wordline X+signal is high (a local wordline is activated). A global reset signal RESET is provided to a reset NFET transistor N3 to reset the latch 334 at the beginning of each refresh period.

Further referring to FIG. 3, the read path 328 includes a read NFET transistor N4 coupled to a read line 339 of the SRAM latch 324, and responsive to a refresh REFX+control signal that specifies a particular latch circuit 322 that corresponds to a local wordline specified by the X+control signal. The REFX+signal is thus used to read the flag bit for a specific latch circuit 322 when performing a refresh operation to provide the flag bit value from the read line 339 (the inverse to that stored on the write line 334) to a wired- or output of all the latch circuit outputs, at 338.

For one embodiment, and further referring to FIG. 3, the wired- or output 338 from the latching logic 320 is fed to a gate terminal 340 of gating transistor N5. When activated, the gating transistor N5 allows for activation of transistor N1 of the activation circuit 302. When disabled, such as when a flag bit is provided from the latching circuitry 320 via the refresh REFX+command, the gating transistor N5 prevents activation of transistor N1, effectively gating or suppressing activation of the wordline bMWL if the specified local wordline has previously been activated during the refresh interval. In some circumstances, a normally-open bypass transistor N6 may be employed in parallel with the gating transistor N5. The bypass transistor N6 is responsive to a command signal bREF, indicating that a refresh operation is not going to occur, thus negating a deactivation of gating transistor N5. This effectively provides a conductive path that allows the activation circuitry transistor N1 to activate the master wordline bMWL even when the gating transistor N5 is off.

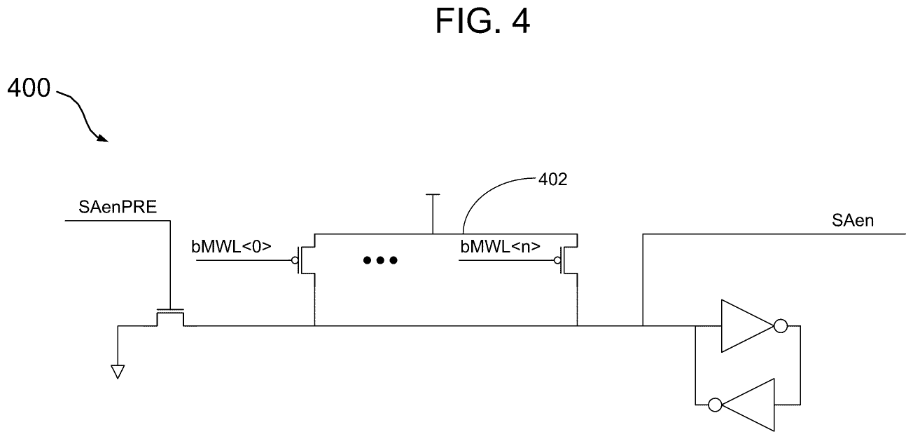

For some embodiments, when suppressing activation of a master wordline during a refresh operation to save power, it may be desirable to also suppress activation of a sense amplifier associated with the suppressed master wordline to save even more power. FIG. 4 illustrates sense amplifier enable circuitry 400 to generate a sense amplifier enable signal SAen, based on a precharge control signal SAenPRE, only when an associated master wordline is activated. The circuit generally monitors, via a wired- or connection at 402, whether any of a block of master wordlines bMWL<0> to bMWL<n> (associated with a given sense amplifier) is activated. If any one of the master wordlines is activated, then the sense amplifier enable signal SAen is “high”, and the sense amplifier circuit associated with the block of wordlines is enabled. If activation of a given master wordline is suppressed, then the sense amplifier enable signal SAen is “low”, and the sense amplifier circuit associated with the given master wordline is disabled. SAenPRE is on if the sense amplifier will not be used, i.e., outside of a row cycle, to turn the sense amplifier off. In a row cycle, SAenPRE goes low and the wired or of the connected bMWL determines the status of SAen.

In operation, a given storage cell 122 of a local wordline may be accessed at a frequency that approaches or occurs more often than a refresh frequency associated with the cell. This access characteristic may be straightforwardly predicted by, for example, recognizing that relatively small memory arrays (up to 500 MB, for example) with page sizes of approximately 1 kB and random access times of 100 ns, or less, have a higher probability of incurring densely timed accesses to a same page that fall within time intervals that are less than the refresh period for the page. Thus, where a page, or local wordline, has already been activated by an ACTIVATE command for a prior access, and incurs at least one additional access within a single refresh period, the page doesn't need to be refreshed by a separate refresh operation. By scheduling memory accesses strategically, and configuring the row decoder circuitry 112 and the refresh control circuitry 124 to cooperate in selectively suppressing refresh operations when unneeded, significant power savings may be realized during operation.

For one embodiment, the refresh control circuitry 124 and the refresh counter circuit 126 are configured to generate RESET commands and set refresh cycles to repeat twice during a predetermined retention time. The predetermined retention time may be determined and set by the memory controller 102 based on the known architecture of the memory device 104. Thus, in one specific implementation, for a retention time of 32 ms, each refresh cycle is configured to repeat every 16 ms, and is initiated by a RESET command signal to clear the latching circuitry 320 of any flag bits.

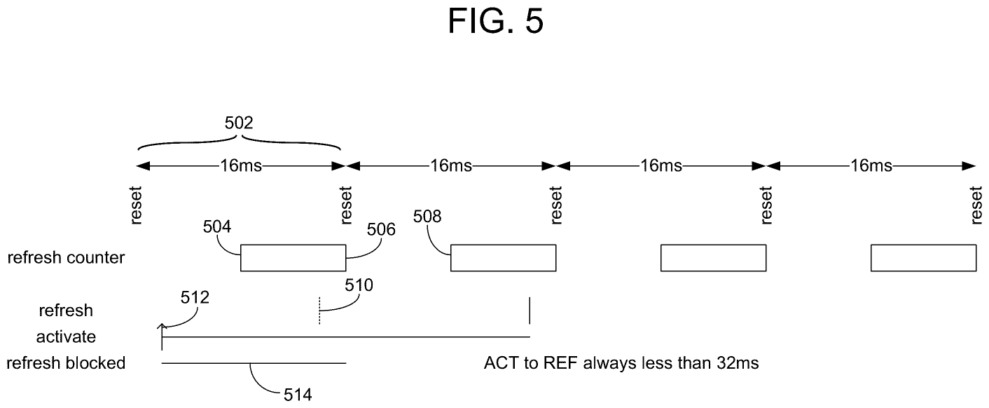

FIG. 5 illustrates generic timing employed by one embodiment of a memory device where the storage cells exhibit an average retention time of approximately 32 ms, and with refresh cycles to repeat twice during the retention time interval. Each 16 ms refresh interval is shown at the top of FIG. 5, at 502. The refresh counter circuit 126 increments through all of the wordlines, beginning at 504, ending at 506, and starting anew at 508. A refresh operation is generally initiated for each wordline corresponding to each increment. For some embodiments, the refresh operations are scheduled by the memory controller 102 to occur in a back-half portion of the refresh interval, by having the refresh counter circuit 126 count through all of the wordlines during the back-half of the 16 ms refresh interval. This serves to increase the chance of suppressing a given “unnecessary” refresh operation. The back-half interval scheduling may be controlled by monitoring the refresh count via the register storage 128, and having the memory controller 102 periodically read the register contents (such as, for example, through mode register read MRR commands) to monitor the count progression, and thus schedule refresh commands appropriately.

Further referring to FIG. 5, and as noted above, as the refresh count circuit 126 increments to a corresponding address of a given wordline, a refresh operation is initiated, such as at 510, for the given wordline. In the event that a preceding ACTIVATE command, such as at 512, activated the given wordline within a given 16 ms refresh interval, such as at 502, then the refresh operation is suppressed, such as shown at 514.

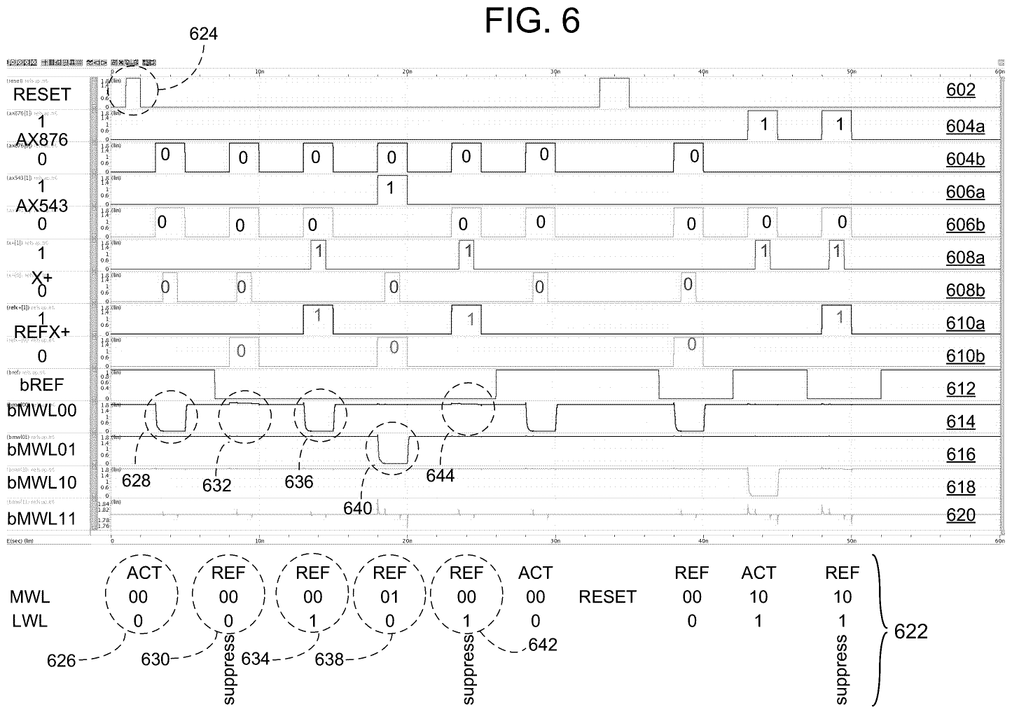

FIG. 6 illustrates relative timing parameters for multiple master wordline circuits during simulated operation, consistent with the circuitry described above with respect to FIG. 3. The top line 602 illustrates a RESET signal waveform to reset any flag bits in the latching circuitry 320, thus initiating the start of a refresh period. Respective one-hot predecoded signals AX876 and AX543 are shown at 604a, 604b, 606a and 606b, while X+waveforms are shown at 608a and 608b. REFX+signals are shown at 610 a and 610b. A bypass signal bREF is illustrated at 612. Master wordline activation waveforms for bMWL00, bMWL01, bMWL10 and bMWL11 are shown at 614, 616, 618 and 620. A corresponding table of activate ACT commands, refresh REF commands, and refresh suppressions are shown at 622 for multiple master wordlines and local wordlines.

Further referring to FIG. 6, a first sequence of wordline refreshes and selective refresh suppressions is initiated, at 624, by a RESET command. The RESET command clears all flag bits that may have been written to the latch circuitry 320 in the previous refresh interval. At 626, a first activate ACT command is received that is associated with an access to master wordline MWL00 and local wordline LWL0. A resulting activation waveform of the master wordline bMWL00 is shown, indicated by a negative pulse, at 628. At 630, a refresh command REF is received that is associated with the previously activated master wordline bMWL00. Unlike the activation pulse shown at 628, an activation (negative pulse) to the master wordline bMWL00 is suppressed, at 632 due to the latch circuitry 320 having stored a flag bit for the local wordline 0. Since the same local wordline and master wordline were previously activated by the activate command at 626 within the same refresh interval, the gating circuit 304 suppressed the immediately following refresh operation to the same local wordline by gating activation of the master wordline bMWL00 in response to the refresh command at 630.

With continued reference to FIG. 6, at 634, a subsequent refresh command REF is received for a refresh operation applied to a different local wordline (LWL1) of the same master wordline bMWL00 activated earlier. Since a different local wordline is activated, the gating circuit 304 does not suppress activation of the master wordline bMWL00, shown at 636. At 638, both the master wordline and local wordline are switched, resulting in activation of the master wordline bMWL01, at 640. At 642, a refresh operation is initiated for the previously activated wordline bMWL00 and local wordline (LWL1). However, since the same master wordline and local wordline combination had been previously activated at 634 for an earlier refresh, the subsequent refresh is suppressed by gating the activation of the master wordline bMWL00 at 644. The remaining sequences shown in FIG. 6 result in similar waveforms to those described above.

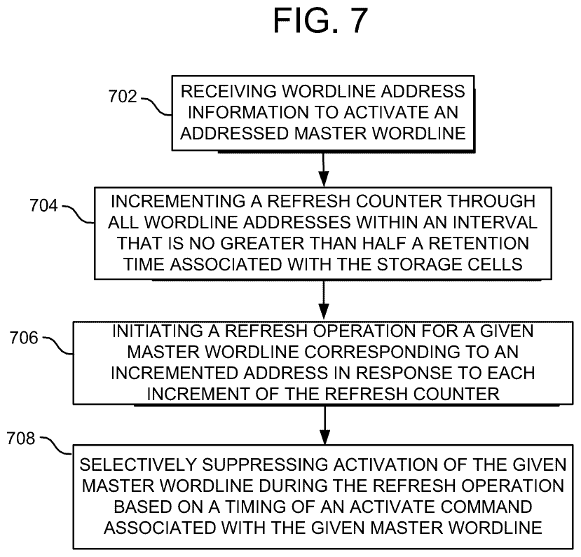

FIG. 7 illustrates high-level steps involved in selectively suppressing a refresh operation for a master wordline consistent with the description associated with the waveform timing diagrams of FIG. 6. At 702, a memory device receives wordline address information from a memory controller to activate an addressed master wordline for a memory access operation during a given refresh interval. During the refresh interval, which in some embodiments is no greater than half the time of a retention time associated with storage cells of the memory device, a refresh counter is incremented, at 704, through all wordline addresses. At 706, a refresh operation is initiated for a given master wordline corresponding to an incremented address in response to each increment of the refresh counter. Activation of the given master wordline is selectively suppressed, at 708, during the refresh operation based on the timing of the activate command associated with the given master wordline.

As noted above, for some embodiments, selectively suppressing refresh operations may be carried out on a modal basis. For instance, the memory controller 102 may statically (a one-time setup) configure the entire memory core 110 of the memory device 104 upon initialization to perform refresh suppressions following activate commands in a manner similar to that described above, or to configure a portion of the memory core circuitry 110 to carry out the selective suppressions. For some embodiments, the modality may be changed in a dynamic or adaptive manner, such as when the memory controller 102 detects an increased density of localized accesses to a small number of pages within relatively short intervals. Such conditions may take advantage of refresh suppression sequences as described above, with the memory controller 102 configuring the memory device 104 (such as through an MRW command to the mode register storage 128) to enable the gate circuitry 304 for selectively suppressing refresh. When the increased access activity tapers, in accordance with more sparse activity, the memory controller 102 may then dynamically reconfigure the memory device 104 to disable the gate circuitry 304 and return to a legacy mode of operation.

Those skilled in the art will appreciate the relatively straightforward circuitry for suppressing unnecessary refresh operations as described above. By employing gating circuitry to selectively suppress activation of a master wordline based on whether the wordline has already been activated in a same refresh period, power savings may be realized in certain applications.

When received within a computer system via one or more computer-readable media, such data and/or instruction-based expressions of the above described circuits may be processed by a processing entity (e.g., one or more processors) within the computer system in conjunction with execution of one or more other computer programs including, without limitation, net-list generation programs, place and route programs and the like, to generate a representation or image of a physical manifestation of such circuits. Such representation or image may thereafter be used in device fabrication, for example, by enabling generation of one or more masks that are used to form various components of the circuits in a device fabrication process.

In the foregoing description and in the accompanying drawings, specific terminology and drawing symbols have been set forth to provide a thorough understanding of the present invention. In some instances, the terminology and symbols may imply specific details that are not required to practice the invention. For example, any of the specific numbers of bits, signal path widths, signaling or operating frequencies, component circuits or devices and the like may be different from those described above in alternative embodiments. Also, the interconnection between circuit elements or circuit blocks shown or described as multi-conductor signal links may alternatively be single-conductor signal links, and single conductor signal links may alternatively be multi-conductor signal links. Signals and signaling paths shown or described as being single-ended may also be differential, and vice-versa. Similarly, signals described or depicted as having active-high or active-low logic levels may have opposite logic levels in alternative embodiments. Component circuitry within integrated circuit devices may be implemented using metal oxide semiconductor (MOS) technology, bipolar technology or any other technology in which logical and analog circuits may be implemented. With respect to terminology, a signal is said to be “asserted” when the signal is driven to a low or high logic state (or charged to a high logic state or discharged to a low logic state) to indicate a particular condition. Conversely, a signal is said to be “deasserted” to indicate that the signal is driven (or charged or discharged) to a state other than the asserted state (including a high or low logic state, or the floating state that may occur when the signal driving circuit is transitioned to a high impedance condition, such as an open drain or open collector condition). A signal driving circuit is said to “output” a signal to a signal receiving circuit when the signal driving circuit asserts (or deasserts, if explicitly stated or indicated by context) the signal on a signal line coupled between the signal driving and signal receiving circuits. A signal line is said to be “activated” when a signal is asserted on the signal line, and “deactivated” when the signal is deasserted. Additionally, the prefix symbol “/” attached to signal names indicates that the signal is an active low signal (i.e., the asserted state is a logic low state). A line over a signal name (e.g., ‘<s̅i̅g̅n̅a̅l̅ n̅a̅m̅e̅>’) is also used to indicate an active low signal. The term “coupled” is used herein to express a direct connection as well as a connection through one or more intervening circuits or structures. Integrated circuit device “programming” may include, for example and without limitation, loading a control value into a register or other storage circuit within the device in response to a host instruction and thus controlling an operational aspect of the device, establishing a device configuration or controlling an operational aspect of the device through a one-time programming operation (e.g., blowing fuses within a configuration circuit during device production), and/or connecting one or more selected pins or other contact structures of the device to reference voltage lines (also referred to as strapping) to establish a particular device configuration or operation aspect of the device. The term “exemplary” is used to express an example, not a preference or requirement.

While the invention has been described with reference to specific embodiments thereof, it will be evident that various modifications and changes may be made thereto without departing from the broader spirit and scope of the invention. For example, features or aspects of any of the embodiments may be applied, at least where practicable, in combination with any other of the embodiments or in place of counterpart features or aspects thereof. Accordingly, the specification and drawings are to be regarded in an illustrative rather than a restrictive sense.

1. A memory device, comprising:
an array of storage cells, each storage cell coupled to one of multiple bitlines and one of multiple local wordlines, and wherein groups of the multiple local wordlines are activated by master wordlines; and
a wordline decoder to receive wordline address information and to selectively activate an addressed wordline corresponding to the wordline address information, the wordline decoder comprising gating circuitry operative during a first mode of operation to selectively suppress activation of the addressed wordline during a refresh operation during a current refresh period based on a timing of an activate command associated with the addressed wordline.

2. The memory device of claim 1, wherein:
the gating circuitry is to selectively suppress activation of the addressed wordline based on whether the addressed wordline was activated by a prior activate command within an immediately preceding refresh period.

3. The memory device of claim 2, wherein the wordline decoder further comprises:
for each of the master wordlines,
a master wordline driver coupled to a given one of the master wordlines to activate the given one of the master wordlines;
a set of one-bit latches that correspond to a group of the multiple local wordlines associated with the given one of the master wordlines, wherein individual ones of the set of one-bit latches are to store a flag bit in response to a corresponding local wordline being activated in response to an activate command; and
wherein the gating circuitry is responsive to detection of a stored flag bit associated with a selected one of the set of one-bit latches to selectively suppress activation of the given one of the master wordlines by the master wordline driver.

4. The memory device of claim 3, further comprising:
a refresh counter that increments through all wordline addresses associated with the array of storage cells within a refresh interval that is no more than half a retention time associated with the array of storage cells; and
wherein a refresh operation for a given master wordline corresponding to an incremented address is carried out in response to each increment of the refresh counter.

5. The memory device of claim 4, wherein:
the set of one-bit latches comprise reset circuitry to receive a reset signal, the reset signal applied to the reset circuitry for each master wordline each time the refresh counter cycles through all of the wordline addresses, the set of one-bit latches responsive to the reset signal to reset any flag bits.

6. The memory device of claim 4, further comprising:
register storage to store a count status value of the refresh counter; and
wherein the count status value is retrievable from the register storage in response to a mode register read command.

7. The memory device of claim 6, further comprising:
receiver circuitry to receive refresh commands from a memory controller; and
wherein a timing of the refresh commands is based on the count status value.

8. The memory device of claim 7, wherein:
the timing of the refresh commands received by the receiver circuitry falls within a trailing half sub-interval of a storage cell retention time interval.

9. The memory device of claim 1, further comprising:
register storage to store a mode value of a first state that represents operation in the first mode of operation, or to store a mode value of a second state that represents operation in a second mode of operation that at least partially disables the gating circuitry for at least a portion of the array of storage cells.

10. The memory device of claim 9, wherein:
a setting of the mode value is based on a density of activate commands associated with portions of the array of storage cells.

11. The memory device of claim 1, wherein:
the array of storage cells comprises an array of dynamic random access memory (DRAM) storage cells.

12. A dynamic random access memory (DRAM) integrated circuit (IC) memory chip, comprising:
an array of storage cells, each storage cell coupled to one of multiple bitlines and one of multiple local wordlines, and wherein groups of the multiple local wordlines are activated by master wordlines;
a wordline decoder to receive wordline address information and to selectively activate an addressed wordline corresponding to the wordline address information, the wordline decoder comprising gating circuitry to selectively suppress activation of the addressed wordline during a refresh operation during a current refresh period based on a timing of an activate command associated with the addressed wordline; and
register storage to store a mode value of a first state that enables the gating circuitry, or to store a mode value of a second state that at least partially disables the gating circuitry for at least a portion of the array of storage cells.

13. The DRAM IC memory chip of claim 12, wherein the wordline decoder further comprises:
for each of the master wordlines,
a master wordline driver coupled to a given one of the master wordlines to activate the given one of the master wordlines;
a set of one-bit latches that correspond to a group of the multiple local wordlines associated with the given one of the master wordlines, wherein individual ones of the set of one-bit latches are to store a flag bit upon a corresponding one of the multiple local wordlines being activated in response to an activate command; and
wherein the gating circuitry is responsive to detection of a stored flag bit associated with a selected one of the set of one-bit latches to selectively suppress activation of the given one of the master wordlines by the master wordline driver.

14. The DRAM IC memory chip of claim 13, further comprising:
a refresh counter that increments through all wordline addresses associated with the array of storage cells within a refresh interval that is no more than half a retention time associated with the array of storage cells; and
wherein a refresh operation for a given master wordline corresponding to an incremented address is carried out in response to each increment of the refresh counter.

15. The DRAM IC memory chip of claim 14, wherein:
the set of one-bit latches include reset circuitry to receive a reset signal, the reset signal applied to the reset circuitry for each master wordline each time the refresh counter cycles through all of the wordline addresses, the set of one-bit latches responsive to the reset signal to reset any flag bits.

16. The DRAM IC memory chip of claim 14, wherein:
the register storage is to store a count status value of the refresh counter; and
wherein the count status value is retrievable from the register storage in response to a mode register read command.

17. The DRAM IC memory chip of claim 16, further comprising:
receiver circuitry to receive refresh commands from a memory controller; and
wherein a timing of the refresh commands is based on the count status value.

18. A method of operating a memory device, the memory device comprising an array of storage cells, each storage cell coupled to one of multiple bitlines and one of multiple local wordlines, and wherein groups of the multiple local wordlines are activated by master wordlines, the method comprising:
receiving wordline address information to activate an addressed wordline;
selectively suppressing activation of the addressed wordline during a refresh operation within a current refresh period based on a timing of an activate command associated with the addressed wordline.

19. The method of claim 18, wherein:
selectively suppressing activation of the addressed wordline is based on whether the addressed wordline was activated by a prior activate command within an immediately preceding refresh period.

20. The method of claim 18, further comprising:
incrementing a refresh counter through all wordline addresses associated with the array of storage cells within a refresh interval that is no more than half a retention time associated with the array of storage cells; and
initiating a refresh operation for a given wordline corresponding to an incremented address in response to each increment of the refresh counter.
